(19) United States
(12) Patent Application Publication
(10) Pub. No.: US 2005/0248924 A1
(43) Pub. Date: Nov. 10, 2005

(54) Thermal interface for electronic equipment

(75) Inventors: Timothy Samuel Farrow, Apex, NC (US); Albert Vincent Makley, Raleigh, NC (US)

Correspondence Address: DILLON & YUDELL LLP, 8911 N. CAPITAL OF TEXAS HWY.,, SUITE 2110, AUSTIN, TX, 78759, US

(73) Assignee: International Business Machines Corporation, Armonk, NY (US)

(21) Appl. No.: 10/842,305

(22) Filed: May 10, 2004

(51) Int. Cl. H05K 7/20

(52) U.S. Cl. 361/704

(57) ABSTRACT

A thermal interface made up of a sheet having an array of alternating pivoting sections, each section having a first end directed away from a first side of the sheet and a second end directed away from the opposite side of the sheet, to bridge a gap between a top surface of a processor package and a bottom surface of a heat sink. The sheet is positioned between the processor package and heat sink before securing the heat sink to the processor package. By pressing the processor package and heat sink together, the pivoting sections press against the two surfaces of the processor package and the heat sink to provide a mechanical pressure interface that promotes thermal conduction between the surfaces. In a preferred embodiment, the sheet also has alternating side cantilever panels that provide additional pressure contacts.

### BACKGROUND OF THE INVENTION

1. Technical Field

The present invention relates in general to the field of electronics, and in particular to electronic chips that generate extraneous heat during normal operation. More particularly, the present invention relates to a method and system for conducting heat away from an integrated circuit, which still more particularly may be a microprocessor.

2. Description of the Related Art

In a typical personal computer (PC), the main heat-generating component among the logic circuits is the processor, also referred to as the Central Processing Unit (CPU) or microprocessor (MP). As illustrated in FIG. 1, a processor 102 is mounted in a socket 104, which is mounted on a (printed) circuit board 106 by mating pins 108 from the processor 102 into the socket 104. As processors continue to grow in performance, so does the heat generated by the processors. To remove heat from processor 102, a heat sink (HS) 110, having a HS base 112 and a plurality of fins 114, is secured to processor 102 by a strap 116. Heat is conducted from the processor 102 to the HS base 112 and the fins 114, which dissipate heat by conduction and convection to ambient air surrounding fins 114.

There are two main thermal resistances to heat that is to be dissipated away from processor 102. The first of these two resistances is caused by the interface between processor 102 and HS base 112, and is referred to as “R Case to HS,” which describes the heat transfer resistance between the case of the processor 102 and the HS 110. The second resistance, known as “R HS to air,” is the internal heat transfer resistance of the HS 110 itself, including the material resistance of HS base 112 and fins 114 as well as the heat transfer resistance of the interface between HS 110 and ambient air, especially the air proximate to fins 114.

The temperature differential between processor 102 and an ambient environment, such as air, is called ΔT. For example, if the operating temperature of processor 102 is 75° C., and the ambient temperature around heat sink 110 is 35° C., then ΔT=75° C.−35° C.=40° C.

Heat resistance is properly the inverse of thermal conductivity, which is usually defined as watts per meter-Kelvin, thus resulting in thermal resistance as being meters-Kelvin per watt. However, by convention, heat resistance in electronics is typically defined as ΔT per watt of power generated by the electronic device. Expressed as a formula, then, where ΔT is the difference in the temperature (in Celsius) between the processor and the ambient air, P is the wattage of the processor, and R is the thermal resistance to heat being transferred away from the processor, then:

$$R = \frac{Δ T}{P}$$

with R generally expressed in units of “degrees C./W” (temperature difference in degrees Celsius per Watt of energy).

In modern computers, the interface resistance between processor 102 and the bottom of HS base 112 (“R Case to HS”) accounts for over half of the total heat transfer resistance. Since air is a very poor conductor of heat, the most effective type of heat transfer from processor 102 to HS base 112 is by heat conduction via contacting surfaces of the bottom of HS base 112 and the top of processor 102. However, minor warping, pits and other features of both these surfaces result in only 1% to 5% of the surfaces actually being in contact. To address this lack of direct physical contact, several approaches have been taken in the past. One approach is to lap and polish the surfaces, but this is time consuming and usually cost prohibitive. Another approach is to use a contact interface, such as a grease 118, which is usually a thermally conductive silicon or filled hydrocarbon grease that conducts heat from processor 102 to HS 110. However, grease 118 is messy and difficult to replace in the field, and fillings, such as metals, used to increase thermal conduction are expensive. Other materials have been suggested to replace grease 118, including graphite material such as Union Carbide's GRAFOIL™, but with only limited improvement over the use of grease 118.

What is needed therefore, is a device that reduces interface thermal resistance between two imperfectly flat surfaces by promoting pressure contact between the two surfaces, such as a case top 120 of processor 102 and the bottom of HS base 112.

### SUMMARY OF THE INVENTION

The present invention is directed to a thermal interface made up of a metallic sheet having an array of alternating pivoting sections, each section having a first end directed away from a first side of the sheet and a second end directed away from the opposite side of the sheet, to bridge a gap between a case top of a processor package and a bottom surface of a heat sink. The sheet is positioned between the processor package and heat sink before securing the heat sink to the processor package. By pressing the processor package and heat sink together, the pivoting sections press against the two surfaces of the processor package and the heat sink, thus providing thermal pressure contacts that provide improved thermal conduction. In a preferred embodiment, the metallic sheet also has alternating side cantilever panels that provide additional thermal pressure contacts.

The above, as well as additional objectives, features, and advantages of the present invention will become apparent in the following detailed written description.

### BRIEF DESCRIPTION OF THE DRAWINGS

The novel features believed characteristic of the invention are set forth in the appended claims. The invention itself, however, as well as a preferred mode of use, further purposes and advantages thereof, will best be understood by reference to the following detailed description of an illustrative embodiment when read in conjunction with the accompanying drawings, where:

FIG. 1 depicts a prior art mounting of a processor using a thermal grease for conducting heat from the processor to a heat sink;

FIG. 2a illustrates an inventive thermally conductive sheet of alternating pivoting panels the rotate (articulate) about separate axes;

FIG. 2b depicts a side-view of the sheet illustrated in FIG. 2a;

FIG. 3a-b illustrate the inventive thermally conductive sheet being positioned between a processor and a heat sink; and

FIG. 4 depicts the inventive thermally conductive sheet after being compressed between the processor and the heat sink as shown in FIG. 3a or FIG. 3b.

### DETAILED DESCRIPTION OF A PREFERRED EMBODIMENT

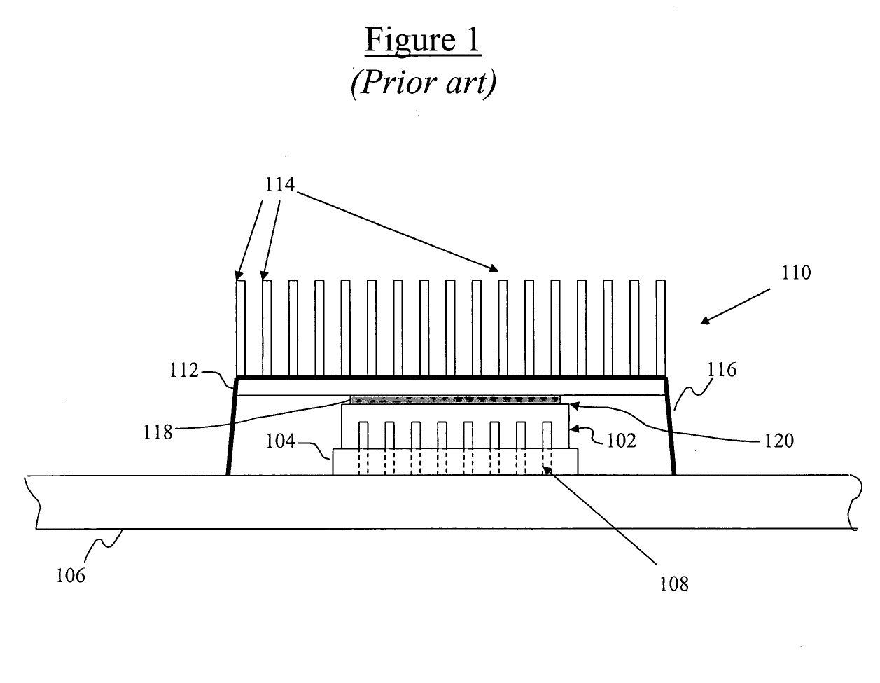

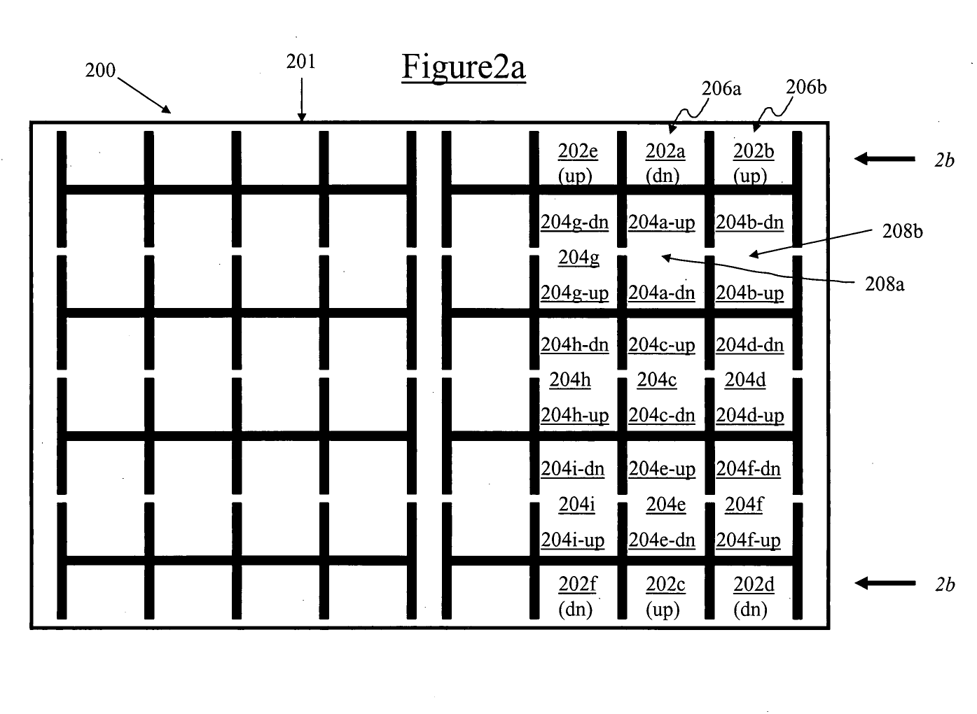

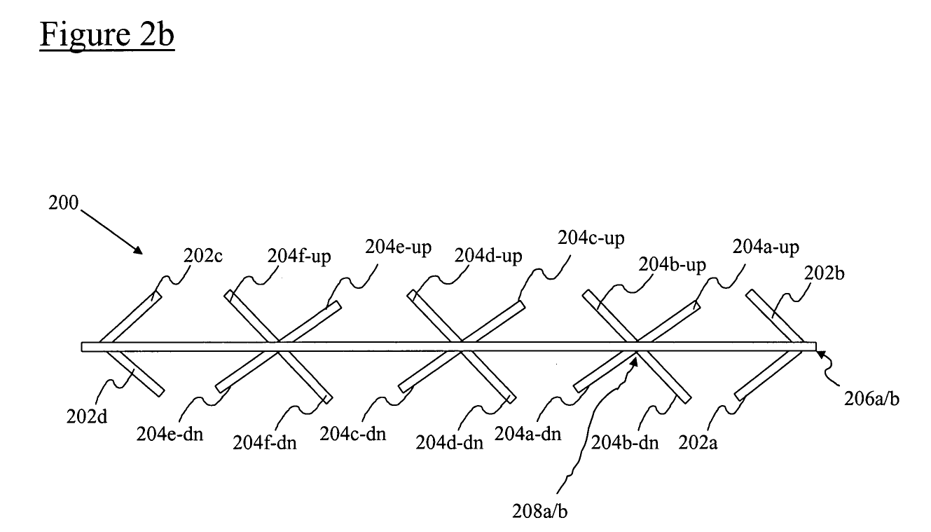

With reference now to FIG. 2a, there is depicted a thermal interface 200 as contemplated by the present invention. Thermal interface 200 is formed from a sheet 201 of thermally conductive material, such as, but not limited to, metal. If metal is used, a preferred metal is copper. Preferably, thermal interface 200 has a same dimension as a case top 120 of processor 102 illustrated in FIG. 1. One such preferred dimension is 38 millimeters by 38 millimeters.

Formed on sheet 201 are multiple pivoting panels 204, of which pivoting panels 204c-i are labeled. Each pivoting panel 204 has a first and second end, labeled as 204x-up or 204x-dn, depending on the direction the end is directed away from sheet 201. While the terms “up” and “down” are used to describe and illustrate this orientation, it is understood that the scope and teaching of the present invention is not limited to particular vertical directions, but rather than the terms are used to described one end being oriented away from a first side of sheet 201, while the second end is oriented away from a second side of sheet 201. That is, each pivoting panel 204 articulates (rotates) about a pivotal axis 208, such as pivotal axis 208a for pivoting panel 204a and pivotal axis 208b for pivotal panel 204b.

The orientation of pivoting panels 204 is illustrated in a side view in FIG. 2b, which depicts a view 2b shown in FIG. 2a.

In addition to pivoting panels 204, sheet 201 preferably also has a plurality of alternating side cantilever panels 202, as shown in FIGS. 2a and 2b, including labeled side cantilever panels 202a-f. Side cantilever panels 202 provide additional thermally conductive pressure contacts between case top 120 and the bottom of HS base 112, as discussed and described below. Each side cantilever panel 202 articulates about a cantilever base 206, such as labeled cantilever bases 206a-f for respective side cantilever panels 202a-f. In a preferred embodiment, alternate side cantilever panels 202 are oriented in opposing directions from sheet 201, as reflected by the labels “up” and “down.” As with the ends of pivoting panels 204, the terms “up” and “down” are not to be construed as limiting the scope of the present invention to vertical orientation.

The alternating orientation of pivoting panels 204 and/or side cantilever panels 202 provides a uniform pressure between case top 120 and the bottom of HS base 112 when thermal interface 200 is compressed between processor 102 and HS base 112.

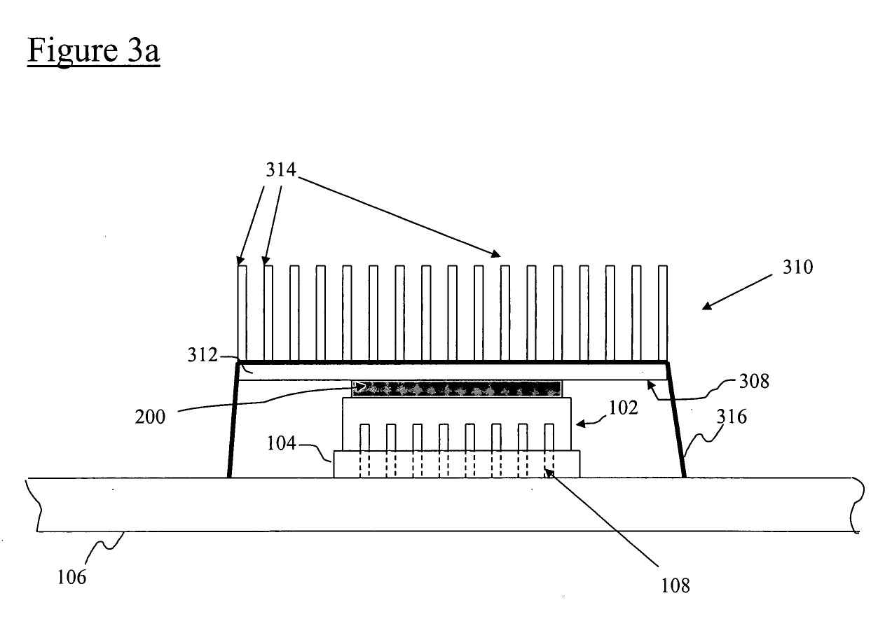

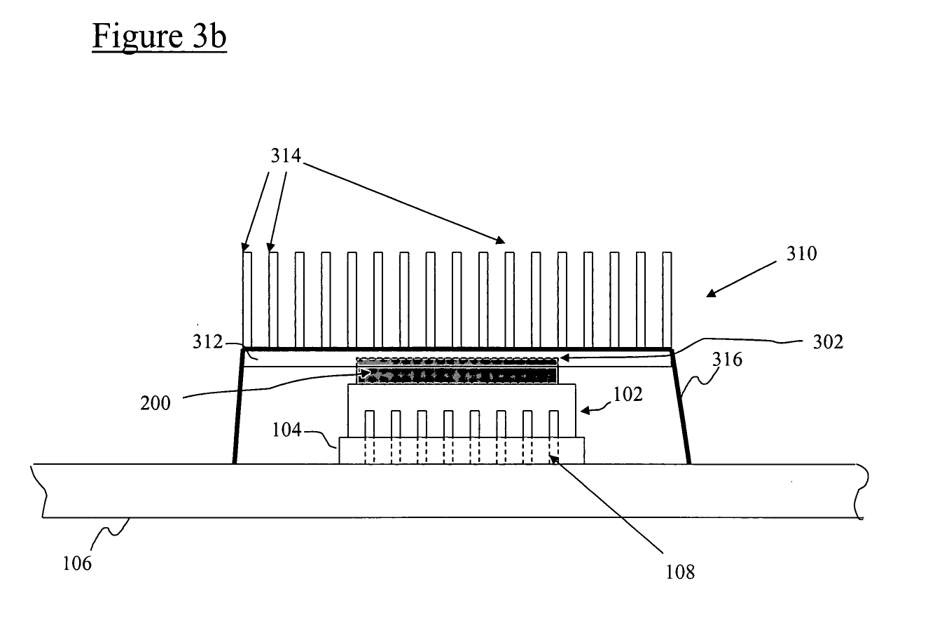

Referring now to FIG. 3a, there is illustrated a side view of processor 102 being mounted in socket 104, which is mounted to circuit board 106. Processor 102 mates with socket 104 using any type of connection method, including but not limited to pins 108, as described in FIG. 1, or any other type of connection known to those skilled in the art, including solder balls, connectors, etc. Alternatively, processor 102 can be directly mounted (usually by soldering) to circuit board 106.

As shown in FIG. 3a, instead of using grease 118 to provide a thermal interface between processor 102 (and particularly case top 120) and a heat sink (HS) 310 (and particularly a HS base 312), the present invention uses thermal interface 200, which is described above in reference to FIG. 2a et seq., to provide such a thermal interface. As thermal interface 200 is compressed, the ends of pivoting panels 204 are pressed against the surfaces of case top 120 and the bottom of HS base 312 to provide thermal pressure contacts. The pressure to the ends of the pivoting panels 204 is provided by the rotational torque of pivotal axes 208. Similarly, the ends of side cantilever panels 202 are pressed against the surfaces of case top 120 and the bottom of HS base 312 to provide additional pressure contacts. The pressure for the ends of the side cantilever panels 202 is provided by cantilever bases 206.

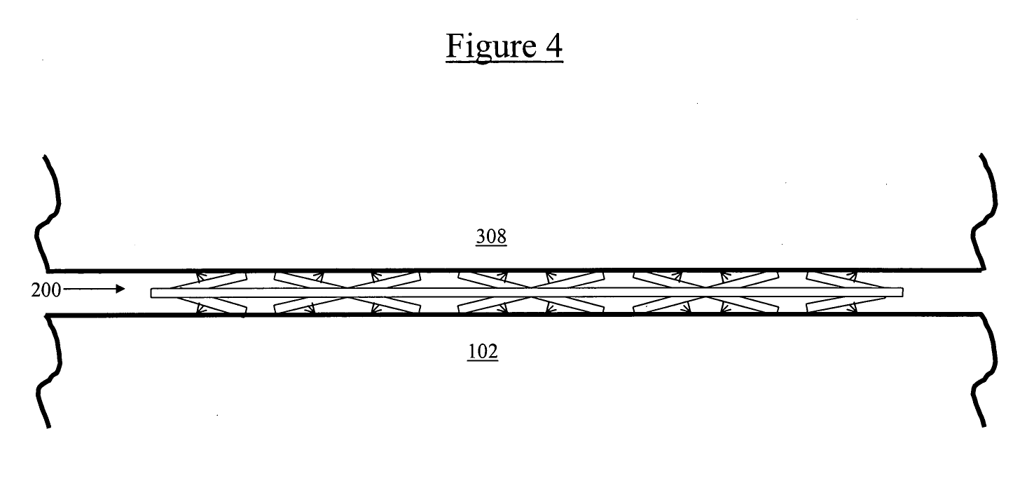

In an alternate preferred embodiment depicted in FIG. 3b, HS base 312 has a cavity 302, in which thermal interface 200 seats to prevent lateral movement when HS 310 is compressed against processor 102. As shown in the embodiment depicted in FIG. 3a, HS base 312 has no cavity 302, allowing thermal interface 200 to compress against a bottom surface 308 of HS base 312. In either embodiment (with or without cavity 302), the compressive load between HS 310 and processor 102 is to be adequate to cause a resistive push-back from the pivoting panels 204 and/or side cantilever panels 202. That is, as shown in FIG. 4, when compressed, each pivoting panels 204 and/or side cantilever panels 202 applies a force as shown by arrows in FIG. 4, resulting in thermal conduction facilitated by the pressure of the force. The force is afforded by rotational torque from pivotal axes 208 and/or cantilever bases 206. Pivotal axes 208 and cantilever bases 206 have a mechanical memory resulting from the positioning of pivoting panels 204 and side cantilever panels 202 away from sheet 201. It is this mechanical memory that creates the rotational torque of pivotal axes 208 and/or cantilever bases 206.

While the invention has been particularly shown and described with reference to a preferred embodiment, it will be understood by those skilled in the art that various changes in form and detail may be made therein without departing from the spirit and scope of the invention. For example, thermal interface 200 has been depicted and described as preferably being the same as a top of processor 102 (e.g., 38 millimeters by 38 millimeters), any sized dimension may be used as appropriate for the application. That is, the dimensions may be adjusted to conform with a flat surface of any electronic or other heat generating device, including but not limited to controllers, transformers, memory chips, etc. Furthermore, while thermal interface 200 has been described as providing an interface between processor 102 and heat sink 310, thermal interface 202 may be used as a thermal interface between any two relatively flat surfaces, in which heat needs to be conducted from one of the relatively flat surfaces to the other relatively flat surface. Further still, while thermal interface 200 is preferably a metallic sheet, any material having sufficient thermal conductivity properties as well as crushable dome tops may be used to construct thermal interface 202. Examples of such materials include, but are not limited to, composite layer materials, nanomaterials such as nano-carbon fibers, and other similar materials.

Furthermore, while rotational torque for pivoting panels 204 and side cantilever panels 202 has been described as being provided by pivotal axes 208 and/or cantilever bases 206 formed from sheet 201, pivotal axes 208 and/or cantilever bases 206 can alternatively be formed by any mechanical device having the ability to provide such rotational torque. An illustrative example of such a mechanical device is a coiled spring having ends pressing against opposite ends of the pivotal panel 204 or against a cantilever base 206 and an associated side cantilever panel 202.

1. A thermal interface comprising:
a sheet made of thermally conductive material;
a first array of pivoting panels, each of the pivoting panels in the first array having first and second ends that resistively articulate about one or more first pivotal axes; and
a second array of pivoting panels, each of the pivoting panels in the second array having first and second ends that resistively articulate about one or more second pivotal axes, the first and second array of pivoting panels being oriented such that each end of the pivoting panels extends away from the sheet in an opposite direction as each orthogonally adjacent end of a same or different pivoting panel, wherein the sheet is oriented between an electronic device and a heat sink to facilitate a transfer of heat from the electronic device to the heat sink when the thermal interface is compressed between the electronic device and the heat sink, thus causing the pivoting panels to resistively articulate about the axes.

2. The thermal interface of claim 1, the sheet also having side cantilever panels oriented in alternately opposing directions, the side cantilever panels resistively articulating about one or more cantilever bases.

3. The thermal interface of claim 1, wherein the sheet is made of a thermally conducting metal.

4. The thermal interface of claim 1, wherein the thermal interface is friction-secured in a cavity in the heat sink, such that an adhesive is not used to secure the thermal interface to the heat sink or the electronic device.

5. The thermal interface of claim 1, wherein the electronic device is a microprocessor mounted on a circuit board.

6. A method comprising:
positioning a sheet made of thermally conductive material between an electronic device and a heat sink, a sheet comprising:
a first array of pivoting panels, each of the pivoting panels in the first array having first and second ends that resistively articulate about one or more first pivotal axes; and
a second array of pivoting panels, each of the pivoting panels in the second array having first and second ends that resistively articulate about one or more second pivotal axes, the first and second array of pivoting panels being oriented such that each end of the pivoting panels extends away from the sheet in an opposite direction as each orthogonally adjacent end of a same or different pivoting panel, wherein the sheet is oriented between an electronic device and a heat sink to facilitate a transfer of heat from the electronic device to the heat sink when the thermal interface is compressed between the electronic device and the heat sink, thus causing the pivoting panels to resistively articulate about the axes.

7. The method of claim 6, wherein the sheet also has side cantilever panels oriented in alternately opposing directions, the side cantilever panels resistively articulating about one or more cantilever bases.

8. The method of claim 6, wherein thermal interface of claim 1, wherein the sheet is made of a thermally conducting metal.

9. The method of claim 6, wherein the thermal interface is friction-secured in a cavity in the heat sink, such that an adhesive is not used to secure the thermal interface to the heat sink or the electronic device.

10. The method of claim 6, wherein the electronic device is a microprocessor mounted on a circuit board.

11. A sheet comprising:
a first array of pivoting panels, each of the pivoting panels in the first array having first and second ends that resistively articulate about one or more first pivotal axes; and
a second array of pivoting panels, each of the pivoting panels in the second array having first and second ends that resistively articulate about one or more second pivotal axes, the first and second array of pivoting panels being oriented such that each end of the pivoting panels extends away from the sheet in an opposite direction as each orthogonally adjacent end of a same or different pivoting panel, wherein the sheet is oriented between an electronic device and a heat sink to facilitate a transfer of heat from the electronic device to the heat sink when the thermal interface is compressed between the electronic device and the heat sink, thus causing the pivoting panels to resistively articulate about the axes.

12. The sheet of claim 11, further comprising side cantilever panels oriented in alternately opposing directions, the side cantilever panels resistively articulating about one or more cantilever bases.

13. The sheet of claim 11, wherein the one or more pivotal axes are formed from the sheet to provide rotational torque to the pivoting panels.

14. The sheet of claim 11, wherein the one or more cantilever bases are formed from the sheet to provide rotational torque to the side cantilever panels.

15. The sheet of claim 11, wherein the sheet is made of a thermally conducting metal.
